(19) United States
(12) Patent Application Publication
(10) Pub. No.: US 2009/0104412 A1
(43) Pub. Date: Apr. 23, 2009

(54) External Light Blocking Film For Display Device, Filter For Display Device Having The Same, And Method Of Fabricating The Same

(75) Inventors: Moon Ki Han, ChungCheongNam-Do (KR); Seung-Ho Moon, ChungCheongNam-Do (KR); In Sung Sohn, ChungCheongNam-Do (KR)

Correspondence Address: LERNER, DAVID, LITTENBERG,;KRUMHOLZ & MENTLIK, 600 SOUTH AVENUE WEST, WESTFIELD, NJ, 07090, US

(73) Assignee: Samsung Corning Precision Glass Co., Ltd., Gyeongsangbuk-do (KR)

(21) Appl. No.: 12/251,599

(22) Filed: Oct. 15, 2008

(30) Foreign Application Priority Data
Oct. 17, 2007 (KR) 10-2007-0104721

(51) Int. Cl. B32B 5/00; B41M 5/30; G03F 7/20

(52) U.S. Cl. 428/195.1; 503/201; 430/321

(57) ABSTRACT

A method of fabricating an external light blocking film for a display device is provided. The method includes a step of applying a curable resin in which a photochromic colorant is mixed on a backing of a transparent resin; a step of disposing a photo-mask having a predetermined pattern on the curable resin and then irradiating the photochromic colorant through the photo-mask with light having a first wavelength which makes the photochromic colorant color-changed; a step of removing the photo-mask and then curing the curable resin. The method can improve fabrication efficiency.

### CROSS-REFERENCE TO RELATED APPLICATION

This application claims the benefit of Korean Patent Application No. 10-2007-0104721 filed on Oct. 17, 2007 with the Korean Intellectual Property Office, the disclosure of which is incorporated herein by reference.

### BACKGROUND OF THE INVENTION

1. Field of the Invention

The present invention relates to an external light blocking film, a filter having the same, and a method of fabricating the same, more particularly the external light blocking film, the filter and the method which can improve a bright room contrast ratio and fabrication efficiency.

2. Description of the Related Art

Display devices include televisions, monitors of personal computers, portable display devices, and so on. The display devices are recently getting larger sized and thinner.

Accordingly, flat panel display (FPD) devices such as plasma display panel (PDP) devices, liquid crystal display (LCD) devices, field emission display (FED) devices, and organic light emitting display (OLED) devices take the place of for cathode ray tube (CRT) device, which was representative of display devices.

Hereinafter, the PDP devices and a filter used therefor will be exemplified but the present invention is not limited thereto. For example, a filter according to the present invention can be used for large sized display devices such as the OLED devices, the LCD devices and the FED devices; small sized display devices such as Personal Digital Assistance (PDA) devices, display devices for small sized games, display devices for small mobile phones; and flexible display devices.

Especially, the PDP device is in the limelight since it has excellent display characteristics such as a high luminance, a high contrast ratio, a low after-image, and a wide viewing angle.

The PDP device causes gas discharge between electrodes by applying a direct or alternating voltage to the electrodes, then fluorescent material is activated by ultraviolet radiation caused by the gas discharge, and thereby light is generated. The PDP device displays images by using the generated light.

However, the PDP device has drawbacks that a large amount of electromagnetic waves and near infrared rays is emitted due to its intrinsic characteristics. The electromagnetic waves and near infrared rays emitted from the PDP device may have a harmful effect to the human body, and cause malfunction of precision appliances such as a cellular phone and a remote controller. Further, the PDP device has high surface reflection and has lower color purity than the CRT device due to orange color light emitted from gas such as He or Xe.

Therefore, the PDP device employs a PDP filter in order to block electromagnetic waves and near infrared rays, reduce light reflection, and improve color purity. The PDP filter is installed in front of a panel assembly. The PDP filter is generally manufactured by adhering or bonding a plurality of functional layers such as an electromagnetic wave blocking layer, etc.

Among the functional layers, an external light blocking film for blocking an external light entering from the outside and absorbing an external light reflected by a panel assembly is used to improve a contrast ratio and luminance.

Generally, a conventional external light blocking film is fabricated by forming a plurality of wedge depressions on a base and then filling the wedge depressions with a black material.

The wedge depressions are formed by a hot pressing method in which a hot mold is pressed onto a thermoplastic resin, a casting method in which a thermoplastic resin is introduced into a mold and then is solidified, an injection molding method, an UV curing method in which an UV curable resin is introduced into a mold and then is cured by ultraviolet rays.

The wedge depressions formed by the above methods are filled with a resin in which a black colorant such as a black pigment and carbon black is mixed and then an external light blocking pattern is completed by using a wiping method, or the like. Generally, this filling process is repeated several times.

To sum up, such conventional methods requires two separate processes, that is, the process of forming the wedge depression on the base and the process of filling the wedge depressions with the black material. In addition, as mentioned above, the filling process is required to be repeated several times. Accordingly, a way of improving fabrication efficiency and reducing fabrication cost is required.

Furthermore, there is a limit on the concentration of the black material which can be used to fill the wedge depression because to increase the concentration of the black material causes increase in cost and makes the filling difficult. For this reason, a creative method of fabricating a new external light blocking film which can improve the efficiency of blocking an external light is required.

### SUMMARY OF THE INVENTION

The present invention is intended to solve the foregoing problems with the conventional art. An object of the present invention is to provide an external light blocking film which can make a fabrication process simple to improve efficiency.

Another object of the present invention is to provide an external light blocking film which can increase the efficiency of absorbing an external light to improve a bright room contrast ratio (BRCR).

In order to attain the above-mentioned objects, the present invention provides an external light blocking film which includes a resin layer and a color-changing colorant mixed in the resin layer, wherein the color-changing colorant is color-changed in a predetermined pattern to form an external light blocking pattern.

Furthermore, the present invention also provides a filter for a display device which includes an external light blocking film, wherein the external light blocking film includes a resin layer and a color-changing colorant mixed in the resin layer, and the color-changing colorant is color-changed in a predetermined pattern to form an external light blocking pattern.

Furthermore, the present invention also provides a method of fabricating an external light blocking film including a first step of forming a resin layer in which a color-changing colorant is mixed, and a second step of color-changing the color-changing colorant in a predetermined pattern to form an external light blocking pattern.

Preferably, in the second step, a mask having the predetermined pattern is disposed over the resin layer and then the color-changing colorant is color-changed in such a manner that the predetermined pattern of the mask is transferred to the color-changing colorant.

Preferably, the color-changing colorant is a photochromic colorant, and in the second step, the photochromic colorant is irradiated with light making the photochromic colorant color-changed in the predetermined pattern.

Preferably, the second step is followed by a third step of curing the resin.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a exploded perspective view schematically illustrating a PDP device;

FIG. 2 is a cross-sectional view schematically illustrating a filter including an external light blocking film according to an embodiment of the present invention; and

FIG. 3 is a view schematically illustrating a method for fabricating the external light blocking film in FIG. 2.

### DETAILED DESCRIPTION OF THE EXEMPLARY EMBODIMENT

The present invention will now be described more fully hereinafter with reference to the accompanying drawings, in which exemplary embodiments thereof are shown.

In the following embodiment, a filter for a PDP device will be exemplified, but as mentioned above, the present invention is not limited thereto.

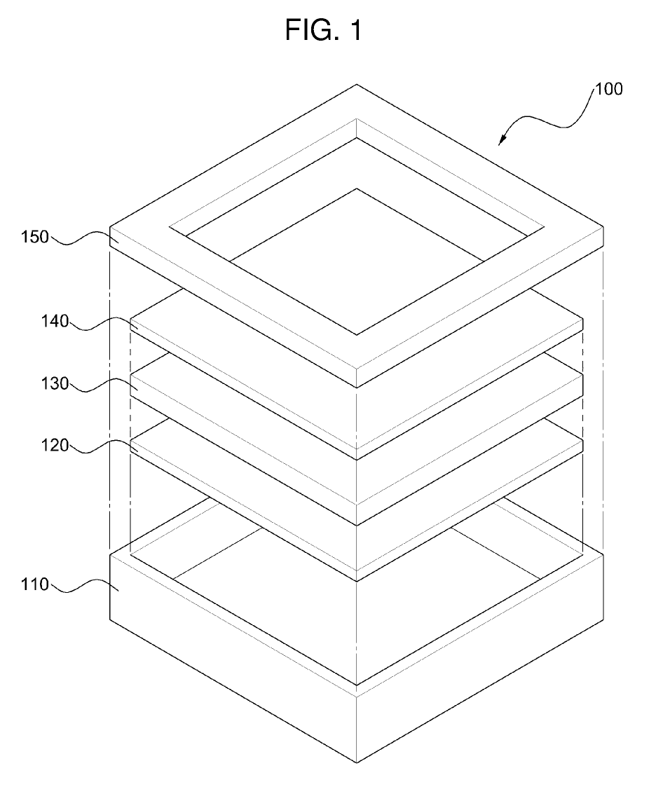

FIG. 1 is an exploded perspective view schematically illustrating a PDP device 100.

Referring to FIG. 1, the PDP device 100 includes a case 110, a cover 150 covering the case 110, a driving circuit board 120 housed in the case 110, a panel assembly 130 including light emitting cells in which gas discharge is generated and a PDP filter 140.

The PDP filter 140 can include an electromagnetic wave blocking layer which includes a very conductive material and is grounded through the cover 150 to the case 110. Before electromagnetic waves reach a viewer, they are discharged through the electromagnetic wave blocking layer and the cover 150 to the case 110.

Hereinafter, a PDP filter according to an embodiment of the present invention will be described in detail.

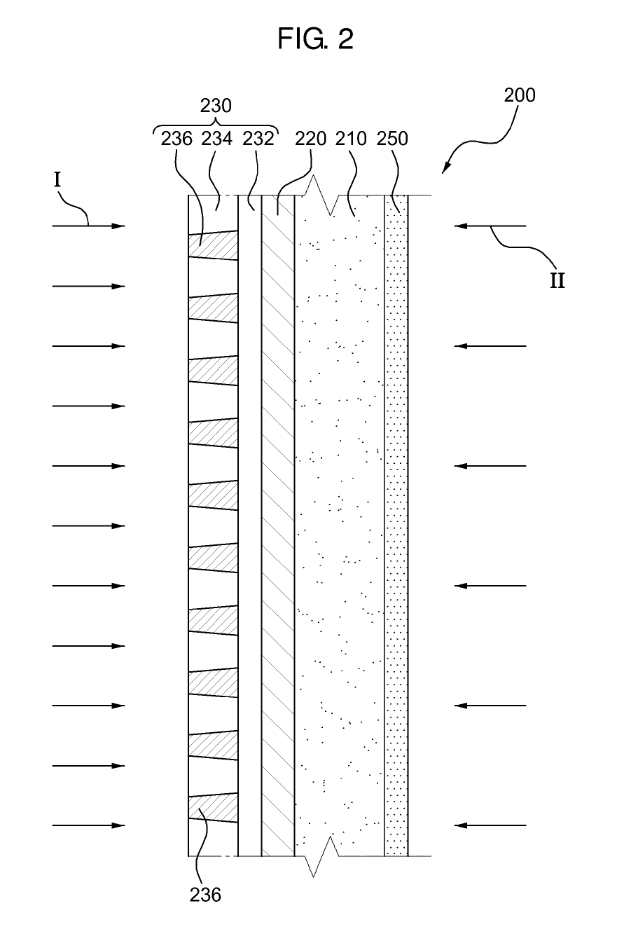

FIG. 2 is a cross-sectional view schematically illustrating the PDP filter 200 including an external light blocking film 230 according to the embodiment.

Referring to FIG. 2, the PDP filter 200 includes a transparent substrate 210, an electromagnetic wave blocking layer 220, and an anti-refection layer 250 as well as the external light blocking film 230.

The PDP filter 200 can include a variety of functional layers such as a color compensation layer, a near infrared ray blocking layer, an anti-glare layer, a hard coating layer, etc, although they are not shown in FIG. 2.

An order in which those layers stack can be varied differently from the order as depicted in FIG. 2.

FIG. 2 shows that the electromagnetic wave blocking layer 220, the anti-reflection layer 250, etc are formed independently of each other, but the present invention is not limited thereto. For example, a filter according to another embodiment of the present invention can include a hybrid layer performing multi-functions.

Each layer can be formed directly on an adjacent layer or can adhere to or bond with an adjacent layer through an adhesive or a bonding agent. Here, the adhesive or the bonding agent can include a color compensation colorant, a near infrared ray blocking colorant, etc. to perform a color compensation function, a near infrared ray blocking function, etc.

The external light blocking film 230 includes a backing 232, a base 234 formed on the backing 232, and an external light blocking pattern 236 formed at the base 234 to block an external light incident toward a panel assembly. However, according to another embodiment, the backing 232 can be excluded.

The external light blocking pattern 236 includes a plurality of pattern units. Hereinafter, the pattern unit will be called an external light blocking part.

In this embodiment, the external light blocking pattern 236 includes a plurality of stripes arranged at the same distance form each other. The external light blocking part is depicted as having a cross section of trapezoid, but the present invention is not limited thereto. For example, the external light blocking part can have a cross section of rectangle, wedge, etc.

The backing 232 supports the base 234 at which the external light blocking pattern 236 is formed. The backing 232 can be made of a transparent polymer resin.

The filter according to the present invention can be installed separately from a panel assembly or can adhere directly to a panel assembly through an adhesive.

The external light blocking part has a trapezoidal shape. A plurality of the external light blocking parts with stripe shapes are formed at the same distance from each other to prevent an external light (11) from entering into the PDP device. Here, an interval between the external light blocking parts and a width of the external light blocking part needs to be optimized to maximize transmittance of light (l) emitted from the panel assembly. A long side of the trapezoidal cross section of the external light blocking part can face the panel assembly and vice versa. In FIG. 2, the long side is depicted as facing a viewer, but the present invention is not limited thereto.

The base 234 includes a resin and a color-changing colorant mixed in the resin.

Preferably, a light curable resin or a thermosetting resin can be used as the resin of the base 234. Especially, when the base 234 includes a light curable resin, it is preferable that a wavelength range (a first wavelength) of light which makes the color-changing colorant color-changed is not different from a wavelength range (a second wavelength) of light which makes the light curable resin cured. Specifically, an acrylic type resin, a silicone resin, a urethane resin can be used.

The color-changing colorant is color-changed in a predetermined pattern to form the external light blocking pattern 236. A photochromic colorant is preferably used as the color-changing colorant, but the present invention is not limited thereto. Other color-changing colorants which are color-changed by a variety of stimuli can be used.

The color of the color-changing colorant is typically changed into a dark color, but the present invention is not limited thereto. For example, the present invention does not exclude the use of decolorization. In this case, a mask will have an inverse pattern.

The photochromic colorant is color-changed or not according to wavelength of light applied thereto. The external light blocking film can use, as the photochromic colorant, a colorant which is irreversibly color-changed. Especially, it is preferable to use the colorant which is transparent before light with a specific wavelength is applied thereto but is changed to have a dark color after the light is applied thereto. If the colorant is not transparent even before the light is applied thereto, the transmittance of the light with the specific wavelength decreases and then the color-changing efficiency of the colorant deteriorates. On the other hand, if the color of the colorant remains light even after the light is applied to the colorant, the external light blocking efficiency of the external light blocking film deteriorates.

The light with the specific wavelength which makes the photochromic colorant color-changed is preferably ultraviolet rays. Accordingly, a colorant which is color-changed by ultraviolet rays can be preferably used as the photochromic colorant. A diazo type colorant can be used.

Generally, a photochromic colorant is color-changed when light with a specific wavelength is applied thereto and is restored to its original color if the light is not applied thereto for a particular time period. Accordingly, the present invention can use a photoinitiator so that the photochromic colorant can not be restored to its original color. The photoinitiator creates a radical when irradiated with ultraviolet rays. An oxide type photoinitiator, an azo type photoinitiator, etc can be used.

In case that the external light blocking pat have a trapezoidal shape as mentioned above, optical effect due to the material thereof as well as optical effect due to the shape thereof can be obtained.

It is preferable that 0.1˜100 parts by weight of the photochromic colorant are used for 100 parts by weight of the polymer resin solids. If a content of the photochromic colorant is less than 0.1 parts, its effect is very minute. On the other hand, a content of the photochromic colorant is more than 100 parts, the polymer resin can not hold the photochromic colorant and thus the photochromic colorant can get out of the polymer resin. More preferably, 1˜20 parts by weight of the photochromic colorant can be used for 100 parts by weight of the polymer resin solids.

A spiro-oxazine type colorant can be used as the photochromic colorant. A plurality of photochromic colorants can be used at the same time. The photochromic colorant can be used together with a thermochromic colorant.

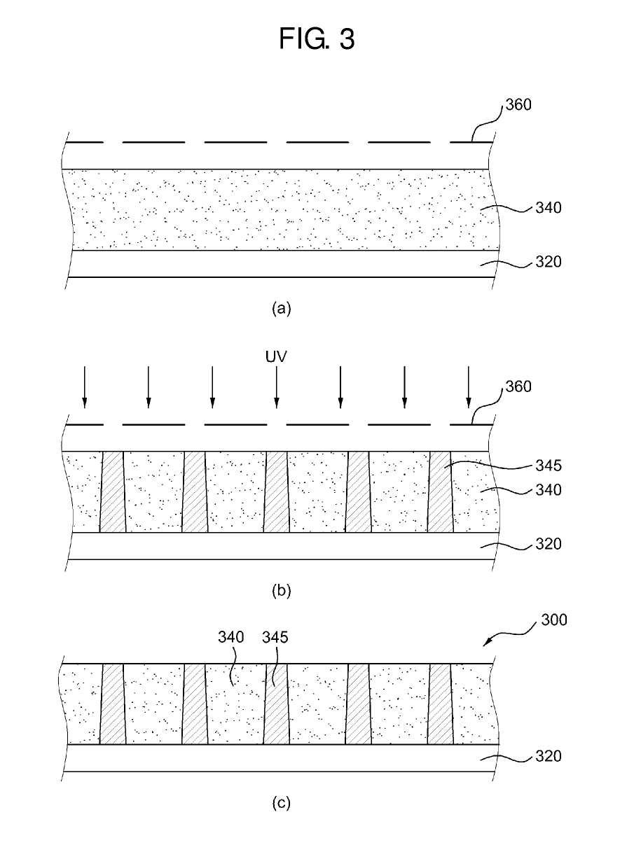

Hereinafter, referring to FIG. 3, a method of fabricating the external light blocking film 300 according to the embodiment of the present invention will be described.

Referring to FIG. 3(a), a curable resin 340 in which the color-changing colorant is mixed is applied on a backing 320. A photo-mask 360 is disposed apart from the curable resin 340. The photo-mask 360 has a pattern in which holes are arranged at the same distance from each other. The distance between the adjacent holes determines a distance between the external light blocking parts.

Referring to FIG. 3(b), the resin 340 is irradiated with ultraviolet rays through the photo-mask 360 and the photochromic colorant is color-changing to form an external light blocking pattern 345. As ultraviolet rays travel further toward the bottom of the resin 340, they spread due to a diffraction phenomenon in such a manner that a width of the ultraviolet rays is wider than a width of the hole. This makes a cross section of the external light blocking part have a trapezoidal shape. For this reason, there is a difference between a length of the long side and a length of the short side of the trapezoidal cross section but the difference is not large. The photochromic colorant is irradiated with ultraviolet rays to be darkened. Since this reaction is irreversible, the photochromic colorant can not be restored to its original color.

According to another embodiment, a transparent backing can be used and ultraviolet rays can be applied through the transparent backing. This can make a short side of a trapezoidal cross section of an external light blocking part face the transparent backing.

Referring to FIG. 3(c), the color-changing is completed to provide the external light blocking pattern 345. The photo-mask 360 is removed and then the curable resin 340 is cured to complete the external light blocking film 300. A light curable resin or a heat curable resin can be used as the curable resin 340. When the light curable resin is used, a wavelength of light which makes the curable resin cured has to be different from a wavelength of light which makes the photochromic colorant color-changed. Otherwise, when the curable resin is cured, the color-changing is carried out again all over the photochromic colorant.

Differently from a conventional method of fabricating an external light blocking film, the method according to the present invention does not require two processes of forming wedge depressions on a base and filling the wedge depressions with a light absorption material. The external light blocking film 300 can be fabricated by a single process of color-changing a predetermined part of the resin 340 in which the photochromic colorant is mixed by using the photo-mask with the predetermined pattern.

What is claimed is:

1. An external light blocking film for a display device comprising: a resin layer and a color-changing colorant mixed in the resin layer,
wherein the color-changing colorant is color-changed in a predetermined pattern to form an external light blocking pattern.

2. The external light blocking film of claim 1,
wherein the color-changing colorant is a photochromic colorant.

3. The external light blocking film of claim 2,
wherein the photochromic colorant is irradiated with light such that color of the photochromic colorant is irreversibly changed into black.

4. The external light blocking film of claim 2,
wherein light making the photochromic colorant color-changed is ultraviolet rays.

5. The external light blocking film of claim 2,
wherein the photochromic colorant is a diazo type colorant.

6. The external light blocking film of claim 1 further comprising a backing,
wherein the resin layer includes a curable resin, and is formed on the backing.

7. The external light blocking film of claim 6,
wherein the curable resin is a light curable resin.

8. The external light blocking film of claim 7,
wherein the color-changing colorant is a photochromic colorant,
the photochromic colorant is color-changed by light having a first wavelength, and
the light curable resin is cured by light having a second wavelength different from the first wavelength.

9. A filter for a display device comprising an external light blocking film,
wherein the external light blocking film includes a resin layer and a color-changing colorant mixed in the resin layer, and the color-changing colorant is color-changed in a predetermined pattern to form an external light blocking pattern.

10. A method of fabricating an external light blocking film for a display device comprising:
a first step of forming a resin layer in which a color-changing colorant is mixed, and
a second step of color-changing the color-changing colorant in a predetermined pattern to form an external light blocking pattern.

11. The method of claim 10,
wherein in the second step, a mask having the predetermined pattern is disposed over the resin layer and then the color-changing colorant is color-changed in such a manner that the predetermined pattern of the mask is transferred to the color-changing colorant.

12. The method of claim 10,
wherein the color-changing colorant is a photochromic colorant, and
in the second step, the photochromic colorant is irradiated with light making the photochromic colorant color-changed in the predetermined pattern.

13. The method of claim 12,
wherein the photochromic colorant is irradiated with the light such that color of the photochromic colorant is irreversibly changed into black.

14. The method of claim 12,
wherein in the first step, the resin layer in which a photoinitiator as well as the color-changing colorant is mixed is formed.

15. The method of claim 12,
wherein the light making the photochromic colorant color-changed is ultraviolet rays.

16. The method of claim 12,
wherein the photochromic colorant is a diazo type colorant.

17. The method of claim 10,
wherein the resin layer includes a curable resin and the external light blocking film includes a backing,
in the first step, the curable resin in which the color-changing colorant is mixed is applied on the backing, and
the second step is followed by a third step of curing the curable resin.

18. The method of claim 17,
wherein the curable resin is a light curable resin.

19. The method of claim 10,
wherein the resin layer includes a curable resin and the external light blocking film includes a backing,
in the first step, the curable resin in which a photochromic colorant is mixed is applied on the backing,
in the second step, a photo-mask having the predetermined pattern is disposed over the curable resin, and then the photochromic colorant is irradiated through the photo-mask with light having a first wavelength which makes the photochromic colorant color-changed, and
the second step is followed by a third step of removing the photo-mask and then curing the curable resin.

20. The method of claim 19,
wherein the curable resin is a light curable resin and is cured by light having a second wavelength different from the first wavelength.
